(19) United States
(12) Patent Application Publication
(10) Pub. No.: US 2016/0344444 A1
(43) Pub. Date: Nov. 24, 2016

(54) CIRCUIT PROTECTION STRUCTURE AND ELECTRONIC DEVICE

(71) Applicant: Xiaomi Inc., Beijing (CN)

(72) Inventors: Dawei YANG, Beijing (CN); Hui LI, Beijing (CN); Dan ZHU, Beijing (CN); Chunli XU, Beijing (CN)

(73) Assignee: Xiaomi Inc., Beijing (CN)

(21) Appl. No.: 14/992,552

(22) Filed: Jan. 11, 2016

(30) Foreign Application Priority Data
May 21, 2015 (CN) 201510263801.1

(51) Int. Cl. H04B 3/28; H05K 7/14; H05K 9/00; H04M 1/02

(52) U.S. Cl. CPC H04B 3/28; H04M 1/0277; H05K 7/1417; H05K 9/0064

(57) ABSTRACT

A circuit protection structure and a device including the same are provided. The circuit protection structure includes: a printed circuit board (PCB) motherboard, a middle frame connected to the PCB motherboard, and a conductive adhesive layer. The PCB motherboard is disposed in a portable electronic device. The PCB motherboard has a circuit unit mounted thereon and a grounded wireframe surrounding a periphery of the circuit unit where the circuit unit contacts the PCB motherboard. The middle frame includes a conductive housing at least partially covering the PCB motherboard the conductive housing having a cavity to enclose the circuit unit. The conductive adhesive layer is disposed between the grounded wireframe and the conductive housing for electrical connection between the grounded wireframe and the conductive housing.

### CROSS-REFERENCE TO RELATED APPLICATIONS

This application is based upon and claims priority to Chinese Patent Application No. 201510263801.1, filed May 21, 2015, the entire contents of which are incorporated herein by reference.

### TECHNICAL FIELD

The present disclosure generally relates to the technical field of communication circuits, and more particularly, to a circuit structure for shielding electromagnetic radiations and an electronic device.

### BACKGROUND

Generally, “noise” in a circuit refers to the redundant signals causing purity distortion to the desired signal. The noise is spread in two ways: conduction and radiation. Generally, the conductive noise is spread from one place to another through a conductor, such as a wire, a printed circuit, a metallic housing of a device, a metallic frame of a device, or components in the circuit, etc. The radiation noise is generally spread from one place to another through air or other dielectric mediums. Further, the conductive noise may be transformed into the radiation noise (i.e., the electromagnetic radiation) when meeting an adaptive antenna.

Several effective methods for reducing noise include shielding, filtering, grounding wire design and overall layout. The conductive noise is generally filtered out by means of traditional circuit technique, and the radiative noise is minimized by means of shielding. The conductive noise may be dealt by means of adding filtering circuit as desired, because the position where the conductive noise exists in the system is commonly already known. However, the radiative noise is hard to be dealt with, for it is usually pervading within the whole system. In order to deal with the radiative noise, a shielding conductive cover may commonly be added to control the radiative noise of the system.

### SUMMARY

According to a first aspect of the present disclosure, there is provided a circuit protection structure. The circuit protection structure includes: a printed circuit board (PCB) motherboard, a middle frame connected to the PCB motherboard, and a conductive adhesive layer. The PCB motherboard is disposed in a portable electronic device. The PCB motherboard has a circuit unit mounted thereon and a grounded wireframe surrounding a periphery of the circuit unit where the circuit unit contacts the PCB motherboard. The middle frame includes a conductive housing at least partially covering the PCB motherboard the conductive housing having a cavity to enclose the circuit unit. The conductive adhesive layer is disposed between the grounded wireframe and the conductive housing for electrical connection between the grounded wireframe and the conductive housing.

According to a second aspect of the present disclosure, there is provided an electronic device. The device includes a housing and at least one circuit protection structure installed within the housing. The circuit protection structure includes: a PCB motherboard, a middle frame connected to the PCB motherboard, and a conductive adhesive layer. The PCB motherboard is disposed in the housing. The PCB motherboard has a circuit unit mounted thereon and a grounded wireframe surrounding a periphery of the circuit unit where the circuit unit contacts the PCB motherboard. The middle frame includes a conductive housing at least partially covering the PCB motherboard the conductive housing having a cavity to enclose the circuit unit. The conductive adhesive layer is disposed between the grounded wireframe and the conductive housing for electrical connection between the grounded wireframe and the conductive housing.

According to a third aspect of the present disclosure, there is provided a smartphone. The smartphone includes a PCB motherboard, a middle frame connected to the PCB motherboard, and a conductive adhesive layer. The PCB motherboard has mounted thereon a first plurality of circuit units and a first grounded wireframe surrounding a first periphery of the first plurality of circuit units. The first plurality of circuit units include a mobile processor and memory connected to the mobile processor. The middle frame includes a conductive housing at least partially covering the PCB motherboard, the conductive housing having a cavity to accommodate the first plurality of circuit unit. The conductive adhesive layer is disposed between the grounded wireframe and the conductive housing, where the conductive adhesive layer is configured to provide an electrical connection between the grounded wireframe and the conductive housing.

It is to be understood that both the foregoing general description and the following detailed description are exemplary and explanatory only and are not restrictive of the disclosure, as claimed.

### BRIEF DESCRIPTION OF THE DRAWINGS

FIG. 1 is an illustrative view showing the partial structure of the circuit protection structure according to the present disclosure in an angle;

FIG. 2 is an illustrative view showing the structure of the circuit protection structure according to the present disclosure in another angle;

FIG. 3 is an illustrative explosive view showing the structure of the circuit protection structure according to an embodiment of the present disclosure;

FIG. 4 is an illustrative explosive view showing the structure of the circuit protection structure according to another embodiment of the present disclosure;

FIG. 5 is an illustrative explosive view showing the structure of the circuit protection structure according to another embodiment of the present disclosure;

FIG. 6 is an illustrative explosive view showing the structure of the circuit protection structure according to another embodiment of the present disclosure; and

FIG. 7 is an illustrative explosive view showing the structure of the circuit protection structure according to another embodiment of the present disclosure.

### DETAILED DESCRIPTION

Detailed description will be made to the present disclosure with reference to the specific implements illustrated by the accompanying drawings. However, the present disclosure is not intended to be limited to the implements. The protection scope of the present disclosure covers any modifications made by those skilled in the art concerning structure, methods or functions according to these implements.

The circuit unit in the present disclosure is protected by forming a structure of Faraday's cage by means of the combination of the conductive housing, the conductive adhesive layer, and the grounded wireframe on the PCB, for the purpose of shielding electromagnetic radiation so as to eliminate or reduce the electromagnetic radiative interference on the circuit unit, without increasing weight and size of the product caused by additional shielding conductive cover, and thus improving competitiveness of the product.

The terms in the present disclosure is used merely for the purpose of description of the particular embodiments, rather than intends to limit the present disclosure. Unless otherwise shown clearly in the context, the singular words “a”, “said” and “the” used in the present disclosure and the appended claims also intend to include the plural. It shall also be appreciated that the term “and/or” used herein refers to and includes any or all possible combinations of one or more relevant listed items.

It shall be appreciated, although various of information in the present disclosure may be described by the terms “first”, “second” and so on, these information is not limited by the terms. These terms are used merely for distinguishing information of the same type from each other. For example, the first information may also be referred as the second information without departing from the scope of the present disclosure. Similarly, the second information may also be referred as the first information. The word “if” used herein may be explained as “when . . . ” or “while” or “response on confirmation”, depending on the context.

Reference throughout this specification to “one embodiment,” “an embodiment,” “exemplary embodiment,” or the like in the singular or plural means that one or more particular features, structures, or characteristics described in connection with an embodiment is included in at least one embodiment of the present disclosure. Thus, the appearances of the phrases “in one embodiment” or “in an embodiment,” “in an exemplary embodiment,” or the like in the singular or plural in various places throughout this specification are not necessarily all referring to the same embodiment. Furthermore, the particular features, structures, or characteristics in one or more embodiments may include combined in any suitable manner.

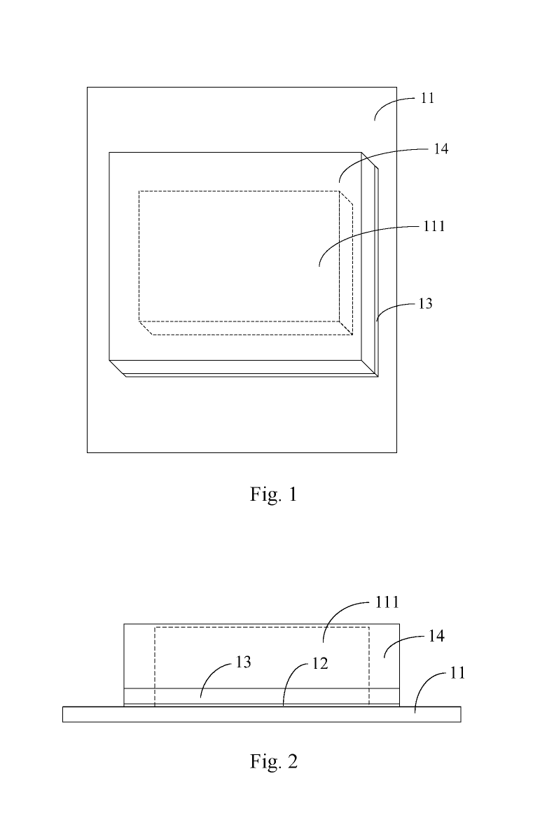

As illustrated in FIGS. 1 and 2, FIG. 1 is an illustrative view showing the partial structure of the circuit protection structure according to the present disclosure in an angle; and FIG. 2 is an illustrative view showing the structure of the circuit protection structure according to the present disclosure in another angle. The circuit protection structure of the present disclosure may include a Printed Circuit Board (PCB) motherboard 11 and a middle frame 16 connected to the PCB motherboard 11. The combination of PCB motherboard 11 and the middle frame 16 provides an enclosing encapsulation for the circuit unit 111 disposed on the PCB ( ) motherboard 11 by means of the principle of the Faraday's cage, so as to shield the outside environment electromagnetic radiation, preventing the electromagnetic radiation from interfering the circuit unit 111. Wherein the circuit unit 111 may be a CPU unit, an audio circuit unit, a video circuit unit, and so on.

In particular, according to the first aspect of the present disclosure, the circuit protection structure of the present disclosure may include: a PCB 11, a grounded wireframe 12, a conductive housing 14 and a conductive adhesive layer 13. Wherein the PCB 11 has thereon a circuit unit 111 and a grounded wireframe 12 surrounding a periphery of the circuit unit 111. The grounded wireframe 12 is formed on the PCB 11 and forms a part of the printed circuit on the PCB 11. The grounded wireframe 12 may either be connected with the main grounding line on the PCB 11, or connected directly with the earth. In an embodiment of the present disclosure, the grounded wireframe 12 has a wire width of no more than 5 mm, and preferably, the grounded wireframe 12 has a width of about 2 mm.

Furthermore, the grounded wireframe 12 is an enclosing structure located on the periphery of the circuit unit 111. In addition, the conductive housing 14 has a receiving cavity for receiving the circuit unit 111. The receiving cavity has a depth (i.e. the size of the conductive housing 14 in the direction of assembling to the circuit unit 111) no less than the height of the highest component in the circuit unit 111. Preferably, in order that the electronic device comprising the circuit protection structure can have a thinner dimension, the receiving cavity may have a depth equal to or slightly more than the height of the highest component in the circuit unit 111.

Furthermore, the conductive housing 14 of the present disclosure is sealed on the grounded wireframe 12 by a conductive adhesive layer 13. Of course, the conductive housing 14 may be further secured later by a bolt or etc. The conductive adhesive layer 13 is disposed between the grounded wireframe 12 and the conductive housing 14 for electrical connection between the grounded wireframe 12 and the conductive housing 14, such that protection circuit structure may form a structure of Faraday's cage, keeping the circuit unit 111 from electromagnetic radiation. Optionally, the conductive adhesive layer 13 and the grounded wireframe 12 of the present disclosure may overlap with each other. Furthermore, the conductive adhesive layer 13 may overlap with the outer edges of the conductive housing 14. The portion of side surface of the conductive housing 14 that contacts with the conductive adhesive layer 13 has the same shape and size as that of the grounded wireframe 12. This arrangement results in an optimal line transmission for the conductive adhesive layer 13 and the grounded wireframe 14, preventing disordered line connection caused by over-wide conductive adhesive layer 13 coming into connection with other lines on the PCB 11, or influenced electrical signal transmission caused by over-narrow conductive adhesive layer 13.

As shown in FIGS. 1-3, in the present disclosure, the conductive adhesive layer 13 is a first conductive foam gasket 131. The opposite sides of the first conductive foam gasket 131 are respectively adhered to the conductive housing 14 and the grounded wireframe 12. Wherein the opposite sides of the first conductive foam gasket 131 both include a conductive double-sided adhesive, such that the first conductive foam gasket 131 may bond the conductive housing 14 and the grounded wireframe 12 together and achieve electrical connection. In the embodiments, the closed structure of Faraday's cage is formed by one side of the first conductive foam gasket 131 being bonded to the grounded wireframe 12, and the other side of the first conductive foam gasket 131 being bonded to the conductive housing 14. What is more, by using the conductive foam gasket having the properties of good conductive and elasticity, the minor gaps between the conductive housing 14 and the PCB 11 may be filled effectively, such that the conductive housing 14 and the PCB 11 may contact completely with each other, so as to solve the problem that the shielding may be weaken due to the incomplete contact between the conductive housing 14 and the PCB 11, which incomplete contact may be caused by deformation of the PCB 11 during installation of the PCB 11.

As shown in FIGS. 1, 2, and 4, in the present disclosure, the conductive adhesive layer 13 is a first conductive silicon gel 132. The opposite sides of the first conductive silicon gel 132 are respectively adhered to the conductive housing 14 and the grounded wireframe 12, such that the conductive housing 14 and the grounded wireframe 12 may be bonded together and achieve electrical connection by the first conductive silicon gel 132. In the embodiments, the closed structure of Faraday's cage is formed by the first conductive silicon gel 132 being bonded respectively to the conductive housing 14 and the grounded wireframe 12, such that the conductive housing 14 and the PCB 11 may contact completely with each other, so as to solve the problem that the shielding may be weaken due to the incomplete contact between the conductive housing 14 and the PCB 11, which incomplete contact may be caused by deformation of the PCB 11 during installation of the PCB 11.

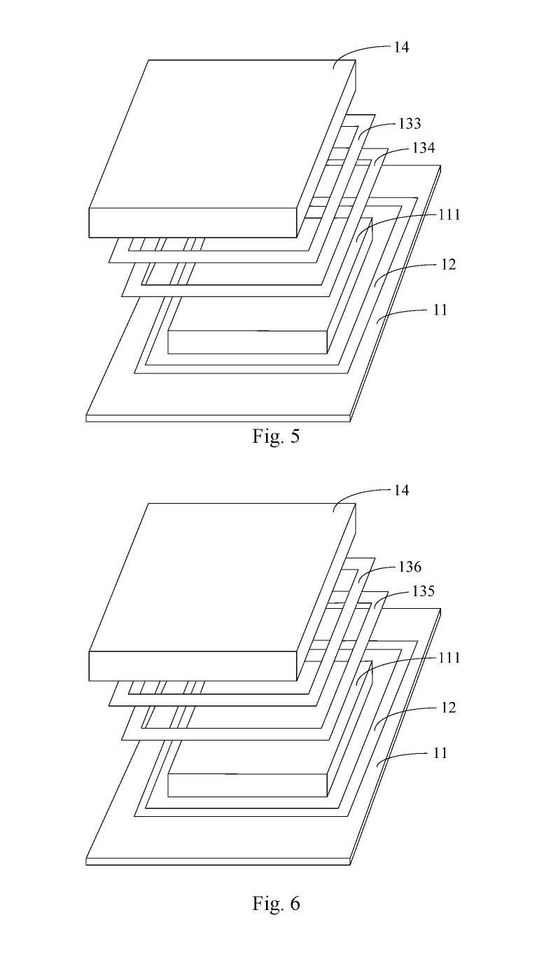

As shown in FIGS. 1, 2, and 5, in the present disclosure, the conductive adhesive layer 13 may include a second conductive foam gasket 133 and a second conductive silicon gel 134 that are attached with each other. The second conductive foam gasket 133 is adhered to the conductive housing 14, and the second conductive silicon gel 134 is adhered to the grounded wireframe 12. In the embodiments, the closed structure of Faraday's cage is formed by one side of the second conductive foam gasket 133 being bonded to the second conductive silicon gel 134, the other side of the second conductive foam gasket 133 being bonded to the conductive housing 14, and the other side, which is departed from the side bonded to the second conductive foam gasket 133, of the second conductive silicon gel 134 being bonded to the grounded wireframe 12. Also, by using the conductive foam gasket having the properties of good conductive and elasticity, the minor gaps between the conductive housing 14 and the PCB 11 existed after electrical connection may be filled effectively, such that the conductive housing 14 and the PCB 11 may contact completely with each other, so as to solve the problem that the shielding may be weaken due to the incomplete contact between the conductive housing 14 and the PCB 11, which incomplete contact may be caused by deformation of the PCB 11 during installation of the PCB 11.

As shown in FIGS. 1, 2, and 6, in the present disclosure, the conductive adhesive layer 13 may include a third conductive foam gasket 135 and a third conductive silicon gel 136 that are attached with each other. Wherein the third conductive foam gasket 135 is adhered to grounded wireframe 12, and the third conductive silicon gel 136 is adhered to conductive housing 14. In the embodiments, the closed structure of Faraday's cage is formed by one side of third conductive foam gasket 135 being bonded to the third conductive silicon gel 136, the other side of the third conductive foam gasket 135 being bonded to the grounded wireframe 12, and the other side, which is departed from the side bonded to the third conductive foam gasket 135, of the third conductive silicon gel 136 being bonded to the conductive housing 14. Also, by using the conductive foam gasket having the properties of good conductive and elasticity, the minor gaps between the conductive housing 14 and the PCB 11 existed after electrical connection may be filled effectively, such that the conductive housing 14 and the PCB 11 may contact completely with each other, so as to solve the problem that the shielding may be weaken due to the incomplete contact between the conductive housing 14 and the PCB 11, which incomplete contact may be caused by deformation of the PCB 11 during installation of the PCB 11.

Furthermore, according to a second aspect of the present disclosure, there is provided an electronic device, comprising a housing and at least one circuit protection structure installed within the housing, the circuit protection structure being the circuit protection structure according to any one of the above-mentioned embodiments. In particular, the circuit protection structure may include: a printed circuit board PCB 11, a grounded wireframe 12, a conductive housing 14, and a conductive adhesive layer 13 disposed between the grounded wireframe 12 and the conductive housing 14 for electrical connection between the grounded wireframe 12 and the conductive housing 14. Wherein the PCB 11 has thereon a circuit unit 111 and a grounded wireframe 12 surrounding a periphery of the circuit unit 111. Preferably, the conductive adhesive layer 13 overlaps with the orthographic projection of the grounded wireframe 12 projecting on the PCB 11, i.e., the conductive adhesive layer overlaps with the grounded wireframe. In the embodiments, the conductive adhesive layer 13 uses the same material and structure as that used in the conductive adhesive layer 13 of the above-mentioned circuit protection unit 111, which will not be repeated here.

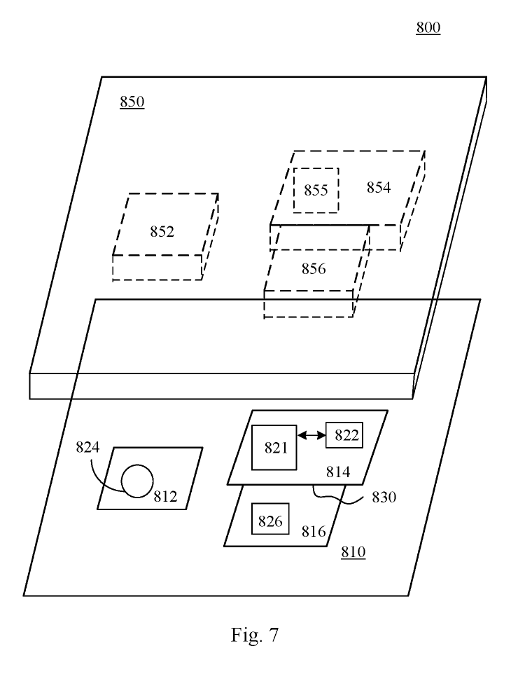

FIG. 7 is an illustrative explosive view showing the structure 800 of the circuit protection structure according to another embodiment of the present disclosure. The structure 800 may be a part of a smartphone that includes a printed circuit board (PCB) motherboard 810. The PCB motherboard 810 includes circuit units mounted thereon. For example, a first plurality of circuit units include a mobile processor 821 and memory 822 connected to the mobile processor 821. A first grounded wireframe 814 surrounds the first periphery of the first plurality of circuit units 821 and 822. The structure 800 further include a middle frame 850 connected to the PCB motherboard 810. The middle frame 850 may include a conductive housing 854 at least partially covering the PCB motherboard, where the conductive housing includes a cavity to accommodate the first plurality of circuit units 821 and 822. The shape of the circuit units and conductive housing are for illustration only and do not limit the claim scope. The conductive housing 854 may include a heat dissipation unit 855 inside the conductive housing 854, where the heat dissipation unit 855 is configured to at least partially touch the mobile processor 821 and dissipate heat generated from the mobile processor 821.

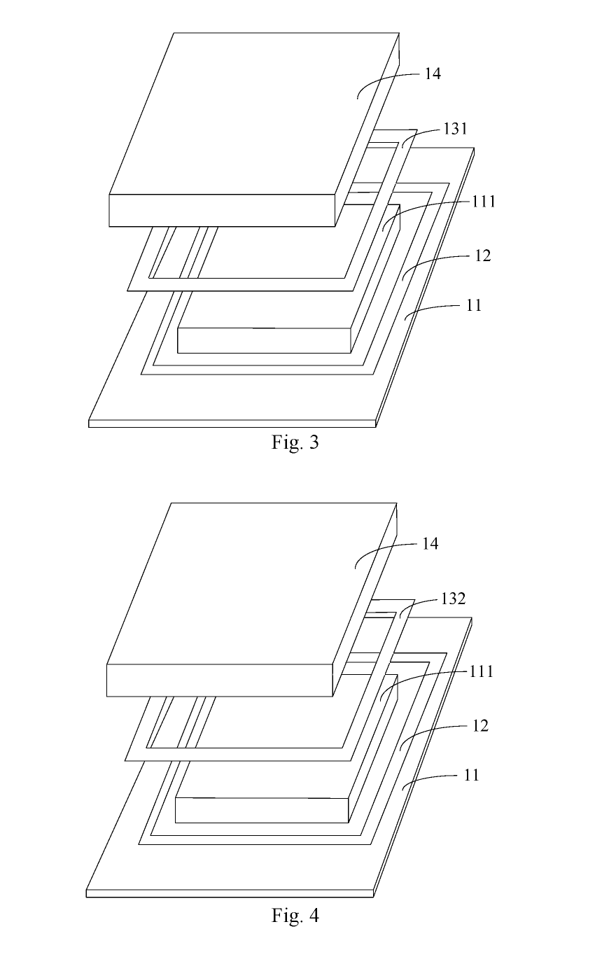

The structure 800 may include a conductive adhesive layer as shown in FIGS. 3-6. The conductive adhesive layer may be disposed between the grounded wireframe and the conductive housing, where the conductive adhesive layer is configured to provide an electrical connection between the grounded wireframe and the conductive housing.

The conductive adhesive layer may include a first conductive foam gasket, where opposite sides of the first conductive foam gasket are respectively adhered to the conductive housing and the grounded wireframe. The PCB motherboard 810 may further include a second plurality of circuit units 826 and a second grounded wireframe 816 surrounding a second periphery of the second plurality of circuit units 826. The first grounded wireframe 814 and the second grounded wireframe 816 may share at least a portion of a straight common grounded wireframe 830. The middle frame 850 includes a second conductive housing 856 configured to cover the second plurality of circuit units 826 on the PCB motherboard 810. The middle frame 850 includes a third conductive housing 852 configured to cover the third plurality of circuit units 824 surrounded by the third grounded wireframe 812.

The circuit unit in the present disclosure is protected by forming a structure of Faraday's cage by means of the combination of the conductive housing, the conductive adhesive layer, and the grounded wireframe, for the purpose of shielding electromagnetic radiation so as to eliminate or reduce the electromagnetic radiative interference on the circuit unit, without increasing weight and size of the product caused by additional shielding conductive cover, and thus improving competitiveness of the product.

Other embodiments of the invention will be apparent to those skilled in the art from consideration of the specification and practice of the invention disclosed here. This application is intended to cover any variations, uses, or adaptations of the invention following the general principles thereof and including such departures from the present disclosure as come within known or customary practice in the art. It is intended that the specification and embodiments be considered as exemplary only, with a true scope and spirit of the invention being indicated by the following claims.

It will be appreciated that the present invention is not limited to the exact structure that has been described above and illustrated in the accompanying drawings, and that various modifications and changes can be made without departing from the scope thereof. It is intended that the scope of the invention should only be limited by the appended claims.

What is claimed is:

1. A circuit protection structure, comprising:
a printed circuit board (PCB) motherboard disposed in a portable electronic device, having mounted thereon a circuit unit and a grounded wireframe surrounding a periphery of the circuit unit where the circuit unit contacts the PCB motherboard;
a middle frame connected to the PCB motherboard, the middle frame comprising a conductive housing at least partially covering the PCB motherboard the conductive housing having a cavity to enclose the circuit unit; and
a conductive adhesive layer, disposed between the grounded wireframe and the conductive housing, the conductive adhesive layer configured to provide an electrical connection between the grounded wireframe and the conductive housing.

2. The circuit protection structure of claim 1, wherein the conductive adhesive layer overleaps with the grounded wireframe.

3. The circuit protection structure of claim 1, wherein the conductive adhesive layer overlaps with an outer edge of the conductive housing.

4. The circuit protection structure of claim 3, wherein the conductive adhesive layer comprises a first conductive foam gasket, wherein opposite sides of the first conductive foam gasket are respectively adhered to the conductive housing and the grounded wireframe.

5. The circuit protection structure of claim 3, wherein the conductive adhesive layer comprises a first conductive silicon gel, wherein opposite sides of the first conductive silicon gel are respectively adhered to the conductive housing and the grounded wireframe.

6. The circuit protection structure of claim 3, wherein the conductive adhesive layer comprises a second conductive foam gasket and a second conductive silicon gel that are attached with each other, wherein the second conductive foam gasket is adhered to the conductive housing, and the second conductive silicon gel is adhered to the grounded wireframe.

7. The circuit protection structure of claim 3, wherein the conductive adhesive layer comprises a third conductive foam gasket and a third conductive silicon gel that are attached with each other, and wherein the third conductive foam gasket is adhered to the grounded wireframe, and the third conductive silicon gel is adhered to the conductive housing.

8. The circuit protection structure of claim 1, wherein the grounded wireframe has a wire width of no more than 5 mm.

9. An electronic device, comprising a housing and at least one circuit protection structure installed within the housing, wherein the circuit protection structure comprises:
a printed circuit board (PCB) motherboard disposed in the housing, having mounted thereon a circuit unit and a grounded wireframe surrounding a periphery of the circuit unit where the circuit unit contacts the PCB motherboard;
a middle frame connected to the PCB motherboard, the middle frame comprising a conductive housing at least partially covering the PCB motherboard, the conductive housing having a cavity to accommodate the circuit unit; and
a conductive adhesive layer, disposed between the grounded wireframe and the conductive housing, the conductive adhesive layer configured to provide an electrical connection between the grounded wireframe and the conductive housing.

10. The electronic device of claim 9, wherein the conductive adhesive layer overlaps with the grounded wireframe.

11. The electronic device of claim 9, wherein the conductive adhesive layer overlaps with an outer edge of the conductive housing.

12. The electronic device of claim 11, wherein the conductive adhesive layer comprises a first conductive foam gasket, wherein opposite sides of the first conductive foam gasket are respectively adhered to the conductive housing and the grounded wireframe.

13. The electronic device of claim 11, wherein the conductive adhesive layer comprises a first conductive silicon gel, wherein opposite sides of the first conductive silicon gel are respectively adhered to the conductive housing and the grounded wireframe.

14. The electronic device of claim 11, wherein the conductive adhesive layer comprises a second conductive foam gasket and a second conductive silicon gel that are attached with each other, wherein the second conductive foam gasket is adhered to the conductive housing, and the second conductive silicon gel is adhered to the grounded wireframe.

15. The electronic device of claim 11, wherein the conductive adhesive layer comprises a third conductive foam gasket and a third conductive silicon gel that are attached with each other, and wherein the third conductive foam gasket is adhered to the grounded wireframe, and the third conductive silicon gel is adhered to the conductive housing.

16. The electronic device of claim 9, wherein the grounded wireframe has a wire width of no more than 5 mm.

17. A smartphone, comprising:
a printed circuit board (PCB) motherboard, having mounted thereon a first plurality of circuit units and a first grounded wireframe surrounding a first periphery of the first plurality of circuit units, the first plurality of circuit units including a mobile processor and memory connected to the mobile processor;
a middle frame connected to the PCB motherboard, the middle frame comprising a conductive housing at least partially covering the PCB motherboard, the conductive housing having a cavity to accommodate the first plurality of circuit units; and
a conductive adhesive layer, disposed between the grounded wireframe and the conductive housing, the conductive adhesive layer configured to provide an electrical connection between the grounded wireframe and the conductive housing.

18. The smartphone of claim 17, wherein the conductive adhesive layer comprises a first conductive foam gasket, wherein opposite sides of the first conductive foam gasket are respectively adhered to the conductive housing and the grounded wireframe.

19. The smartphone of claim 17, wherein the PCB motherboard further comprising a second plurality of circuit units and a second grounded wireframe surrounding a second periphery of the second plurality of circuit units; and wherein the first grounded wireframe and the second grounded wireframe share at least a portion of a straight common grounded wireframe.

20. The smartphone of claim 17, wherein the conductive housing comprises a heat dissipation unit inside the conductive housing, the heat dissipation unit configured to at least partially touch the mobile processor and dissipate heat generated from the mobile processor.
